(19) United States
(12) Patent Application Publication
(10) Pub. No.: US 2024/0186206 A1
(43) Pub. Date: Jun. 6, 2024

(54) INTEGRATED TOP SIDE POWER DELIVERY THERMAL TECHNOLOGY

(71) Applicant: Intel Corporation, Santa Clara, CA (US)

(72) Inventors: Satish PRATHABAN, Beaverton, OR (US); Ramaswamy PARTHASARATHY, Bangalore (IN); Biswajit PATRA, Bangalore (IN); Tongyan ZHAI, Portland, OR (US); Jeff KU, Taipei City (TW); Min Suet LIM, Penang (MY); Yi HUANG, Shanghai (CN); Kai XIAO, Portland, OR (US); Gene F. YOUNG, St. Augustine, FL (US); Weimin SHI, Tigard, OR (US)

(21) Appl. No.: 18/438,450

(22) Filed: Feb. 10, 2024

Related U.S. Application Data
(63) Continuation of application No. PCT/CN2021/140789, filed on Dec. 23, 2021.

(51) Int. Cl. H01L 23/367; H01L 23/00; H01L 23/427; H01L 25/065; H01L 25/18; H05K 1/02

(52) U.S. Cl. CPC H01L 23/367; H01L 23/427; H01L 25/0655; H01L 25/18; H05K 1/0203; H05K 1/0262; H01L 24/16; H01L 2224/16225; H01L 2924/1427; H01L 2924/15311

(57) ABSTRACT

Systems, apparatuses and methods may provide for technology that includes a voltage regulator, a board assembly including a die and a circuit board electrically coupled to a first side of the die, and a thermal dissipation assembly thermally and electrically coupled to a second side of the die, wherein the thermal dissipation assembly is further electrically coupled to the voltage regulator. In one example, the thermal dissipation assembly includes a vapor chamber and the technology further includes a plurality of copper plates electrically coupled to the voltage regulator and a package substrate containing the die, wherein the plurality of copper plates are further thermally coupled to the vapor chamber.

### CROSS-REFERENCE TO RELATED APPLICATIONS

This application is a continuation application of International Application No. PCT/CN2021/140789, filed on Dec. 23, 2021, entitled “INTEGRATED TOP SIDE POWER DELIVERY THERMAL TECHNOLOGY”, the entire disclosure of which is incorporated herein by reference.

### TECHNICAL FIELD

Embodiments generally relate to power delivery in computing systems. More particularly, embodiments relate to integrated top side power delivery thermal technology.

### BACKGROUND

Conventional computing systems may include a processing unit die (e.g., graphics processing unit/GPU die) that receives an operating voltage from a voltage regulator mounted on a motherboard. In such a case, the power delivery path may include the motherboard, power contacts on the motherboard, and a package substrate containing the processing unit die. As the TDP (thermal design point) of the computing system increases to meet performance requirements, losses in the power delivery path (e.g., power losses) from the voltage regulator to the die (e.g., load) also increase squared to the current (current (I) squared times resistance (R), i²R).

### BRIEF DESCRIPTION OF THE DRAWINGS

The various advantages of the embodiments will become apparent to one skilled in the art by reading the following specification and appended claims, and by referencing the following drawings, in which:

FIG. 1 is a plan view of an example of the width of a critical core and fan diameters in a computing system;

FIG. 2A is a comparative side view of an example of a conventional power delivery path and ground connection, and a power delivery path and ground connection according to an embodiment;

FIG. 2B is a side view of an example of a power delivery path and ground connection according to another embodiment;

FIG. 2C is a side view of an example of a voltage regulator that is mounted to a package substrate according to an embodiment;

FIG. 3 is a comparative perspective view of conventional voltage regulator mountings and a voltage regulator mounting on a thermal dissipation assembly according to an embodiment;

FIG. 4A is a comparative side view of an example of a conventional power delivery path in a computing system containing a vapor chamber and an enhanced power delivery path in a computing system containing a vapor chamber according to an embodiment;

FIG. 4B is a plan view of an example of a computing system that includes a plurality of copper plates according to an embodiment;

FIG. 4C is an enlarged perspective bottom view of an example of a spring clip according to an embodiment;

FIG. 4D is a perspective bottom view of an example of a plurality of copper plates according to an embodiment;

FIG. 4E is an exploded perspective view of an example of a copper pedestal, a plurality of copper plates, a thermally conductive adhesive, and a vapor chamber according to an embodiment;

FIG. 4F is a plan view of an example of a computing system that includes a vapor chamber according to an embodiment;

FIG. 4G is a sectional view taken along lines A-A in FIG. 4F;

FIG. 4H is an enlarged view of an example of a spring clip that mates with a terminal of a charge storage device according to an embodiment;

FIG. 4I is an enlarged bottom view of an example of a plurality of copper plates according to an embodiment;

FIG. 4J is a comparative plan view of an example of a conventional semiconductor package and semiconductor packages according to embodiments;

FIG. 5 is a perspective view of an example of a plurality of a plurality of voltage regulator modules mounted to a heat sink according to an embodiment;

FIG. 6 is a perspective view of an example of a regulator board and a voltage regulator that is mounted to the regulator board according to an embodiment;

FIG. 7 is a perspective view of an example of a voltage regulator that is mounted to a package substrate according to an embodiment;

FIG. 8 is a plan view of an example of a high-speed channel according to an embodiment;

FIG. 9 is a perspective view of an example of a processing unit design for a plurality of voltage regulator modules according to an embodiment;

FIG. 10 is a perspective view of an example of a processing unit design for a single voltage regulator according to an embodiment; and

FIG. 11 is a perspective view of an example of a processing unit design with integrated connectors according to an embodiment.

### DETAILED DESCRIPTION OF EMBODIMENTS

Embodiments provide a three-dimensional (3D) power architecture that is integrated into thermal solutions and delivers power to a processing unit die from the top side of the semiconductor package. The technology described herein can substantially reduce overall power losses (e.g., 50-80%, 60 Watts (W) to 30 W-12 W), as well reduce the overall package size by partitioning the power and IO (input/output) vertically—main power enters from the top of the package and I/O enters from the bottom of the vertical stacks. This approach helps to enhance performance required and maintain relatively small form factors for packages and PCB (printed circuit board) layers.

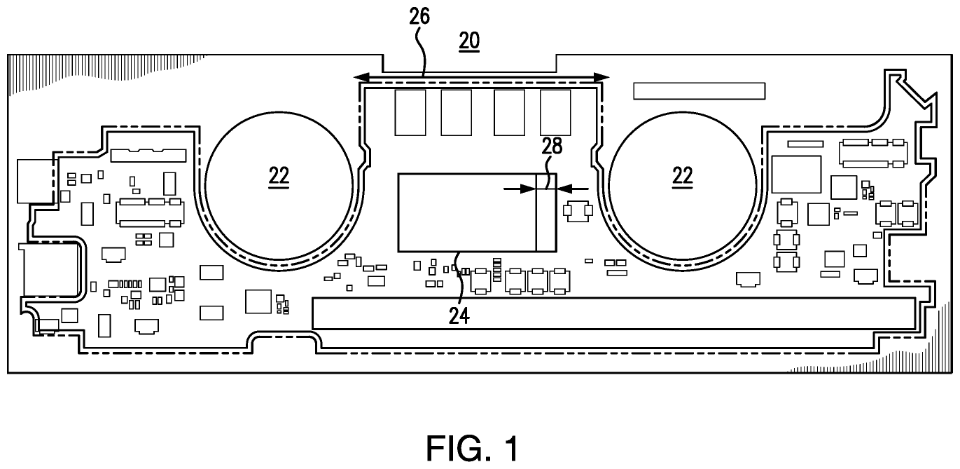

Turning now to FIG. 1, a computing system 20 is shown in which regions 22 contain fans, a region 24 contains a semiconductor package (e.g., containing one or more processing unit dies), and a region 26 contains critical core components. An increase 28 in the width of the region 24 and an increase in the width of the region 26 generally reduces the amount of space available for the fans. As a result, a negative impact on performance may be encountered.

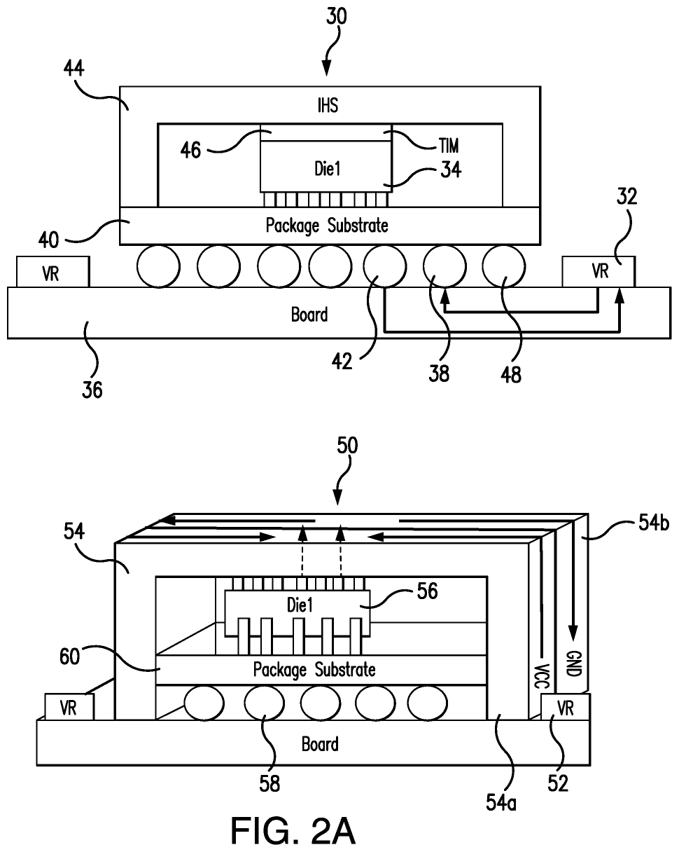

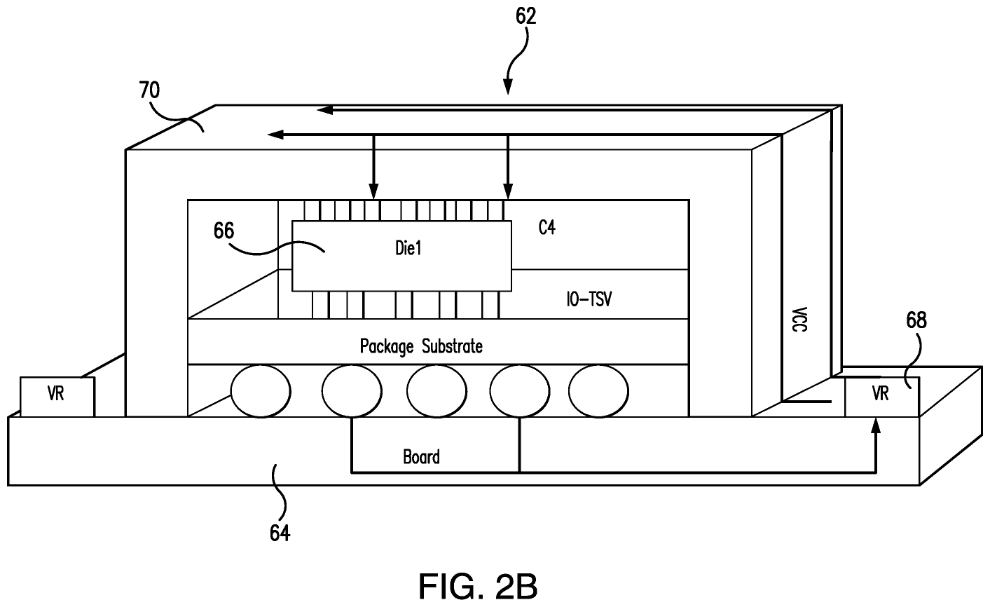

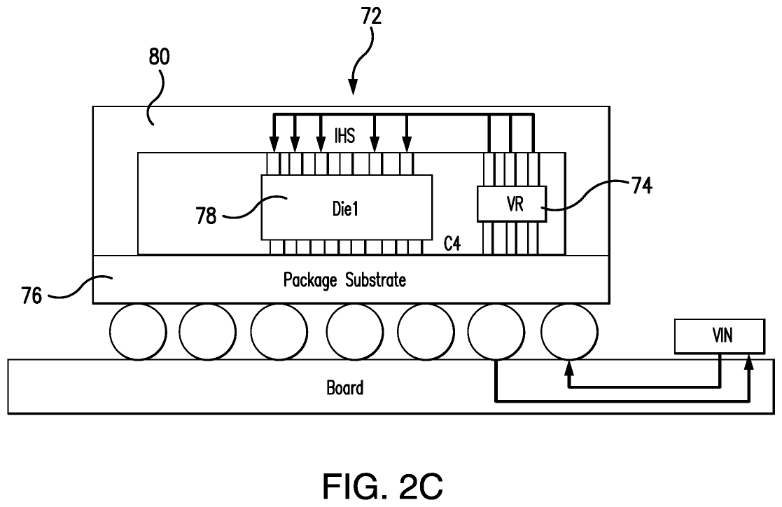

FIG. 2A shows a conventional computing system 30 in which a voltage regulator (VR) 32 supplies power to a die 34. In the illustrated example, the power path includes one or more layers of a circuit board 36, a power contact 38, a package substrate 40, and one or more power bumps (e.g., C4 solder bumps) on a bottom side of the die 34. Similarly, a ground connection between the die 34 and the voltage regulator 32 includes ground bumps on the bottom side of the die, the package substrate 40, a ground pin 42, and one or more layers of the circuit board 36. IO signals are sent to IO bumps on the bottom side of the die 34 through one or more signal pins 48 and the package substrate 40. The conventional computing system 30 also includes an integrated heat spreader (IHS) 44 that is thermally coupled to the die 34 via a thermally conductive material (e.g., adhesive). Power losses in the conventional computing system 30 may be substantial (e.g., worst case DC (direct current) resistance of 1.17 mOhm (milliOhm) and a power loss of 755 μW (microWatt), for an operating voltage of 1V (Volt) and a load of 1 A (Amperes)) due to the resistance drop across the power path.

An enhanced computing system 50 includes a voltage regulator 52 that supplies power to a die 56. In the illustrated example, the power path includes a thermal dissipation assembly such as, for example, an integrated heat spreader 54 (54a, 54b). More particularly, a first heat spreader 54a is electrically coupled to the voltage regulator 52 and carries an operating voltage (e.g., V_{CC}) from the voltage regulator 52 to one or more power bumps on a top side of the die 56. Additionally, a second heat spreader 54b is electrically coupled to the voltage regulator 52 and provides a ground connection from one or more ground bumps on the top side of the die 56 to the voltage regulator 52. The first heat spreader 54a and the second heat spreader 54b are electrically isolated from one another. In an embodiment, IO signals are sent to IO through-silicon vias (TSVs) on the bottom side of the die 56 through one or more signal pins 58 and the package substrate 60. The integrated head spreader 54 is also thermally coupled to the top side of the die 56 to remove heat from the die 56 during operation.

The enhanced computing system 50 substantially reduces power losses (e.g., worst case DC resistance of 0.38 mOhm and a power loss of 670 μW, for an operating voltage of 1V and a load of 1 A). The power savings also enable the operating frequency of the die 56 to be increased (e.g., by 200 MHZ (megahertz), enhancing performance) while staying within the same TDP. Moreover, the power and IO dis-aggregation helps reduce the size of the package. For example, for a 37.5×37.5 mm (millimeter) package with a total of 1200 pins/bumps including 500 signal pins, 380 ground (GND) pins, and approximately 320 power pins, pin dis-aggregation reduces the package size to approximately a 30×30 mm size.

FIG. 2B shows another enhanced computing system 62 in which a circuit board 64 provides a ground connection from the bottom side of a die 66 to a voltage regulator 68. In the illustrated example, an integrated heat spreader 70 is thermally and electrically coupled to the top side of the die 66. The integrated heat spreader 70 is also electrically coupled to the voltage regulator 68. Thus, the integrated heat spreader 70 provides a power delivery path from the voltage regulator 68 to the top side of the die 66. In the illustrated example, power losses are reduced even further (e.g., worst case DC resistance of 0.239 mOhm and a power loss of 391 μW, for an operating voltage of IV and a load of 1A). The power savings also enable the operating frequency of the die 56 to be increased (e.g., by 250 MHz, enhancing performance) while staying within the same TDP.

FIG. 2C shows another enhanced computing system 72 in which a voltage regulator 74 is mounted to a package substrate 76 and supplies power to a die 78 that is also mounted to the package substrate 76. In an embodiment, an integrated heat spreader 80 provides the power delivery path from the regulator 74 to the top side of the die 78. In the illustrated example, power losses are reduced even further (e.g., worst case DC resistance of 22 Ohm, for an operating voltage of IV and a load of 1 A). The power savings also enable the operating frequency of the die 78 to be increased (e.g., by 350 MHZ, enhancing performance) while staying within the same TDP.

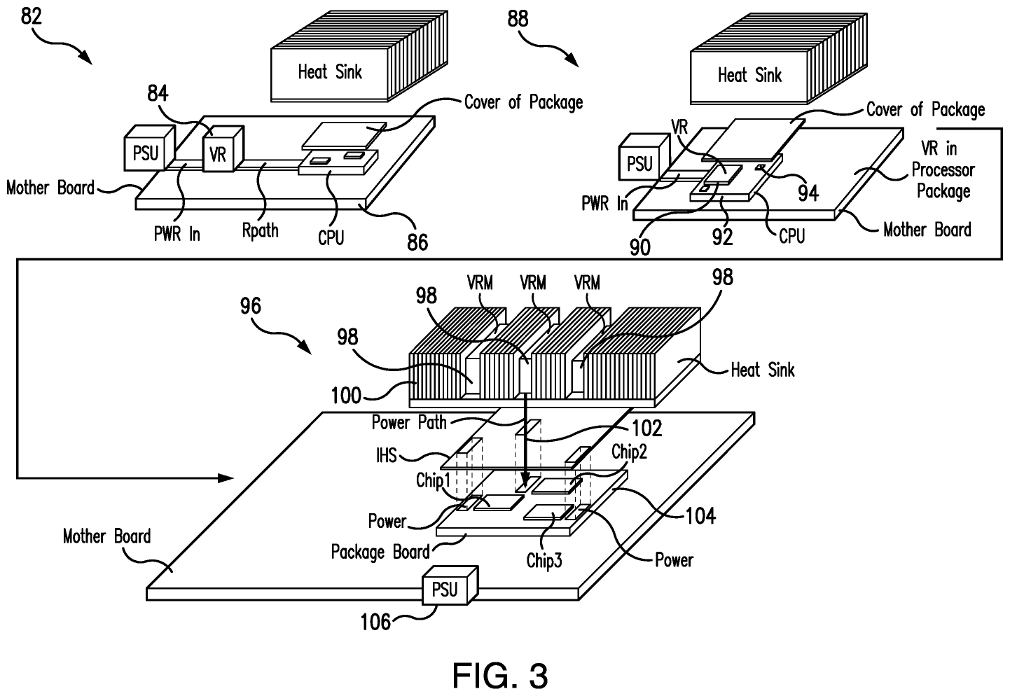

Turning now to FIG. 3, a first conventional computing system 82 is shown in which a VR 84 is mounted to a motherboard 86 and the power delivery path is through the motherboard 86. A second conventional computing system 88 shows a VR 90 mounted to the same package substrate 92 as a processing unit die 94, wherein the power delivery path is through the package substrate 92. In an enhanced computing system 96, a plurality of VR modules (VRMs) 98 are mounted to a heat sink 100. In one example, moving the main power and ground pins to the top side/surface of a package substrate 104 (e.g., containing multiple chips) reduces the package size. In an embodiment, the plurality of VRMs 98 address power imbalances of the multiple chips on the package substrate 104. Thus, a power path 102 is much shorter than the power paths of the conventional computing systems 82, 88. The power pin from the VRMs 98 to the package substrate 104 are more flexible. Additionally, the input voltage from a power supply unit (PSU) to the VRMs 98 is more flexible. In one example, more high speed IO (HSIO) pins may be added to the bottom side of the package substrate 104.

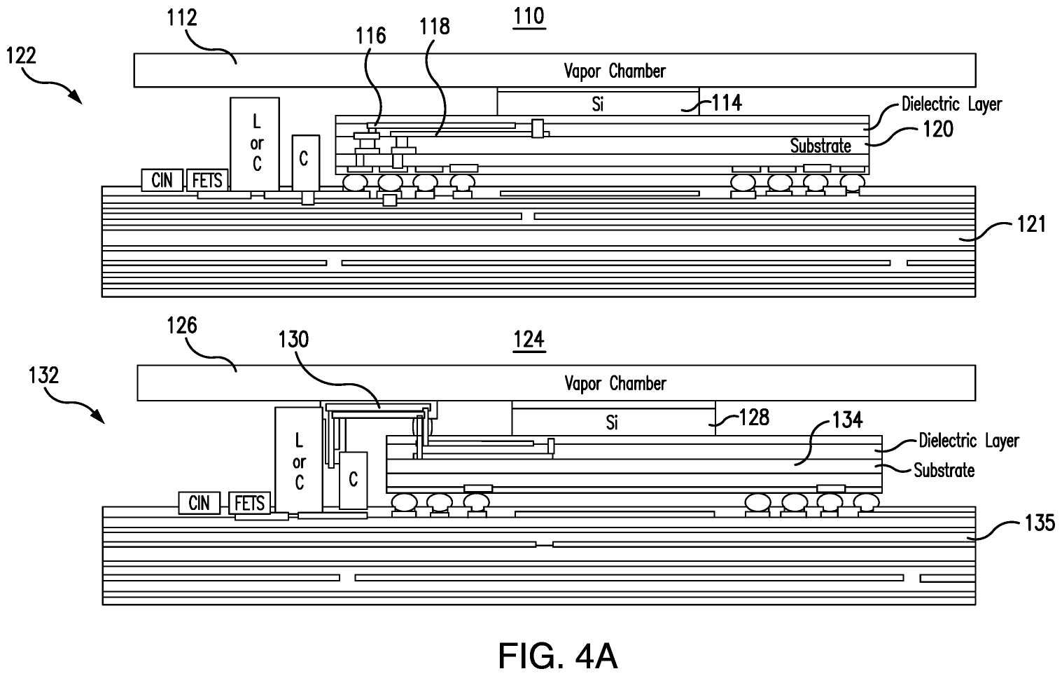

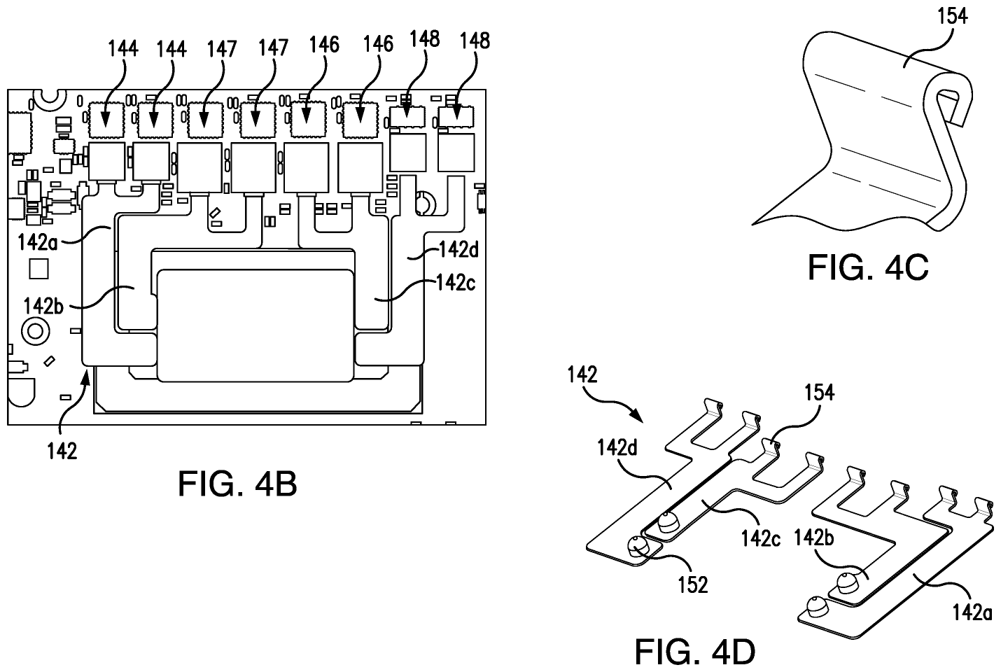

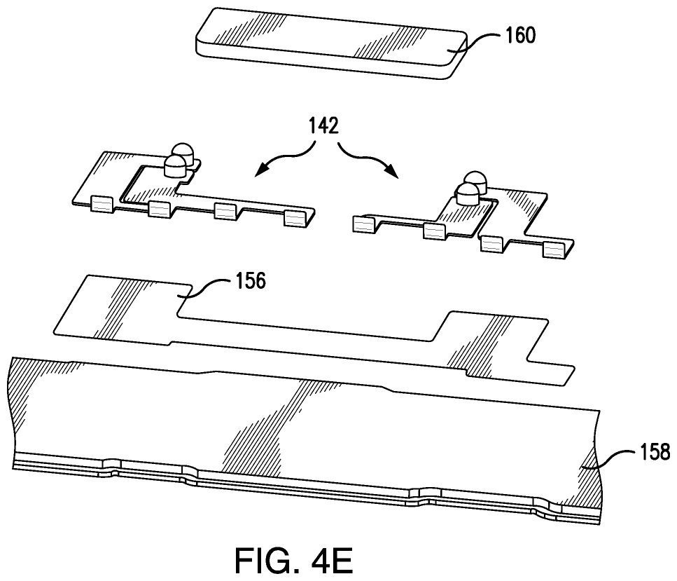

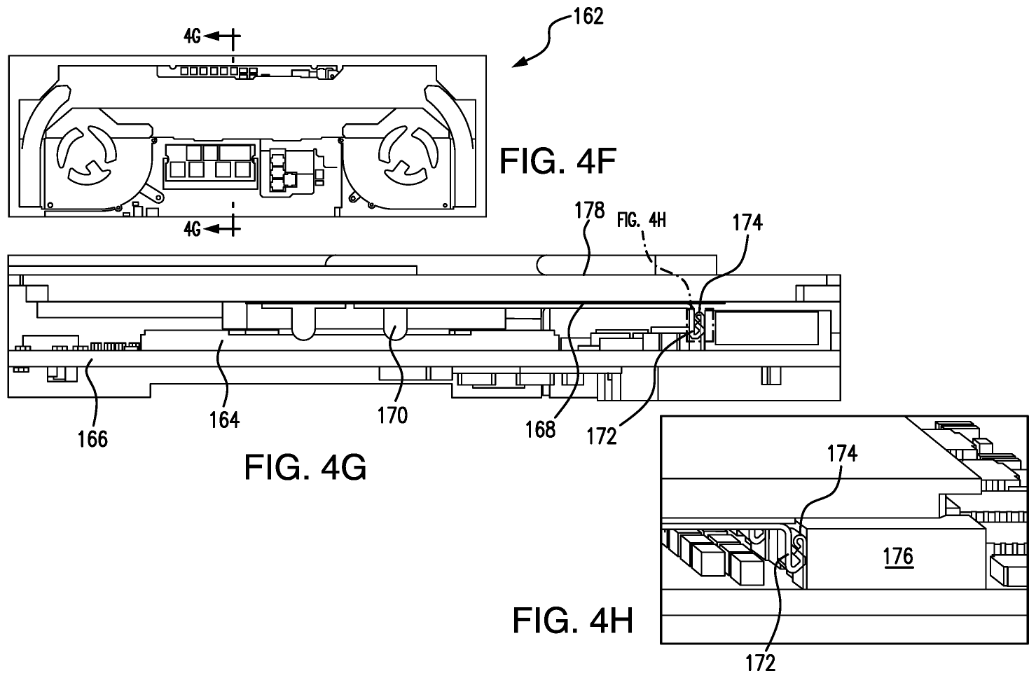

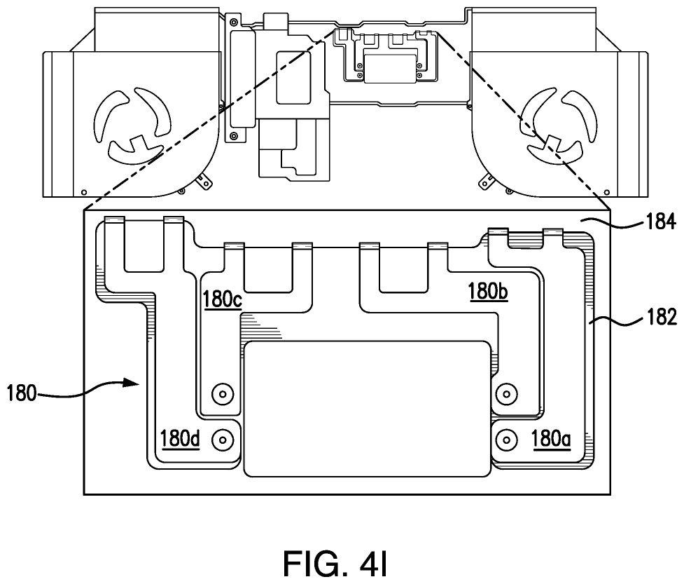

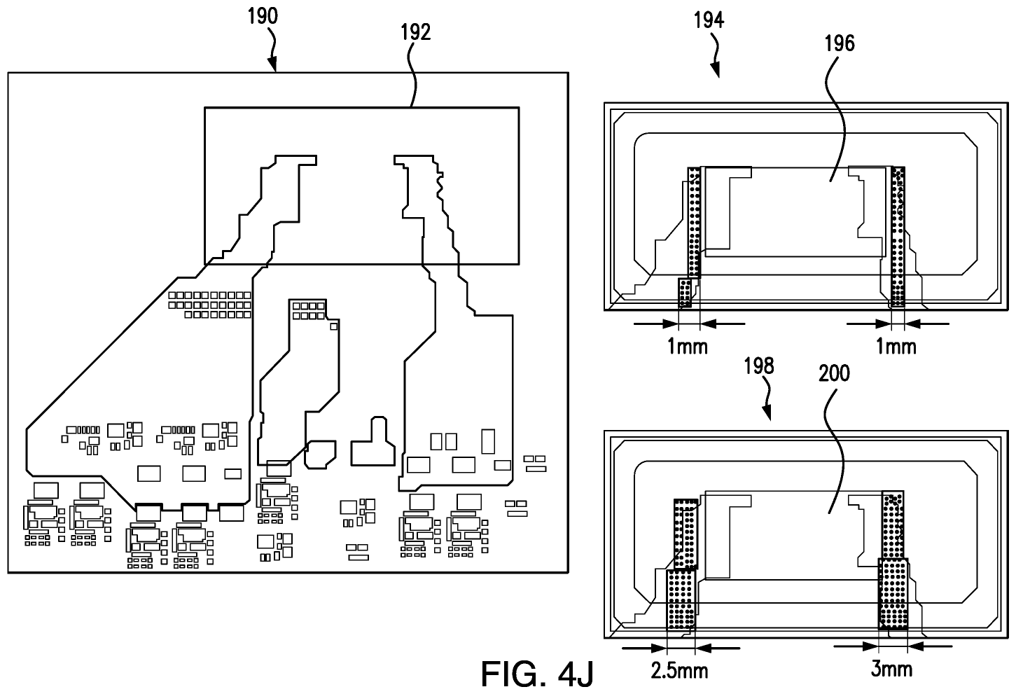

FIG. 4A shows a conventional computing system 110 that includes a vapor chamber (e.g., two-dimensional (2D) thermal dissipation assembly) that is thermally coupled to the top side of a silicon (Si) die 114. In the illustrated example, a power path 116 and a ground connection 118 between the bottom side of the die 114 and VR components 122 (e.g., field effect transistors (FETs) and charge storage devices such as, for example, an inductor (I), a capacitor (C), etc.) are routed through a path on a PCB motherboard 121 to a substrate 120 of the die 114. In an enhanced computing system 124, a vapor chamber 126 is also thermally coupled to the top side of a silicon die 128. In the illustrated example, copper plates 130 provide a power path and ground connection between the bottom side of the die 128 and VR components 132, wherein the power path and the ground connection are not routed through a path on a PCB motherboard 135 to a substrate 134 of the die 128.

FIG. 4B shows a top side view of a computing system 140 in which a plurality of copper plates 142 (142a-142d) are electrically coupled to a first set 144 of VR components (e.g., inductors), a second set 147 of VR components (e.g., inductors), a third set 146 of VR components (e.g., inductors), and a fourth set 148 of VR components (e.g., inductors). The plurality of copper plates 142 are also electrically coupled to a package substrate 150 containing a die and thermally coupled to a vapor chamber. In an embodiment, each copper plate 142 provides a dedicated power delivery rail from the voltage regulator to the package substrate 150. For example, a first copper plate 142a provides a dedicated power delivery rail from the first set 144 of VR components, a second copper plate 142b provides a dedicated power delivery rail from the second set 147 of VR components, a third copper plate 142c provides a dedicated power delivery rail from the third set 146 of VR components, and a fourth copper plate 142d provides a dedicated power delivery rail from the fourth set 148 of VR components.

FIGS. 4C and 4D demonstrate that a first end of each copper plate 142 may include a pogo pin 152 electrically coupled to the package substrate and a second end of each copper plate 142 includes a spring clip 154 that mates with a terminal of a charge storage device associated with the VR.

FIG. 4E shows an expanded view of the copper plates 142 relative to a thermally conductive adhesive 156 positioned between the vapor chamber 158 and the plurality of copper plates 142. Additionally, a copper pedestal 160 may be positioned between the vapor chamber and the top side of the die.

Turning now to FIGS. 4F-4H, a sectional view of a computing system 162 is shown. In the illustrated example, a CPU package 164 is mounted to a circuit board 166. A first end of a copper plate 168 includes a pogo pin 170 that contacts a pad on the CPU package 164 and a second end of the copper plate 168 includes a spring clip 172 that mates with a terminal 174 of a charge storage device 176 (e.g., inductors) associated with a VR. Thus, the spring clip 172 provides a snap feature to interlock with a pad of the charge storage device 176. The copper plate 168 is thermally coupled to a vapor chamber 178.

FIG. 4I is a bottom side view demonstrating that the thin and wide cross-sectional area of each of a plurality of copper plates 180 (180a-180d) provides a significant current carrying capability (e.g., 15A for a 5 mm by 0.25 mm cross-section). As already noted, a thermally conductive adhesive 182 may be positioned between the vapor chamber 184 and the copper plates 180. In one example, the thermally conductive adhesive 182 is electrically insulative. Additionally, the copper plates 180 may be made of a copper alloy with an elasticity that facilitates the use of spring clips at the contact edge. A relatively high thermal conductivity in the copper plates 180 improves the cooling capability of the vapor chamber 184. Accordingly, the illustrated solution provides cost and current carrying capability advantages relative to conventional solutions.

FIG. 4J shows a conventional computing system 190 containing a processing unit package 192 that is relatively large (e.g., 50×25 mm) due to all power pins (e.g., host processor and graphics processor power pins) being placed on the bottom of the package 192. By contrast, a first enhanced computing system 194 brings 15% of the power pins to the top side of a processing unit package 196. As a result, a 2 mm size reduction is achieved in the x-dimension. Indeed, a second enhanced computing system 198 brings 50% of the power pins to the top side of a processing unit package 200. The result is a 5.5 mm size reduction in the x-dimension.

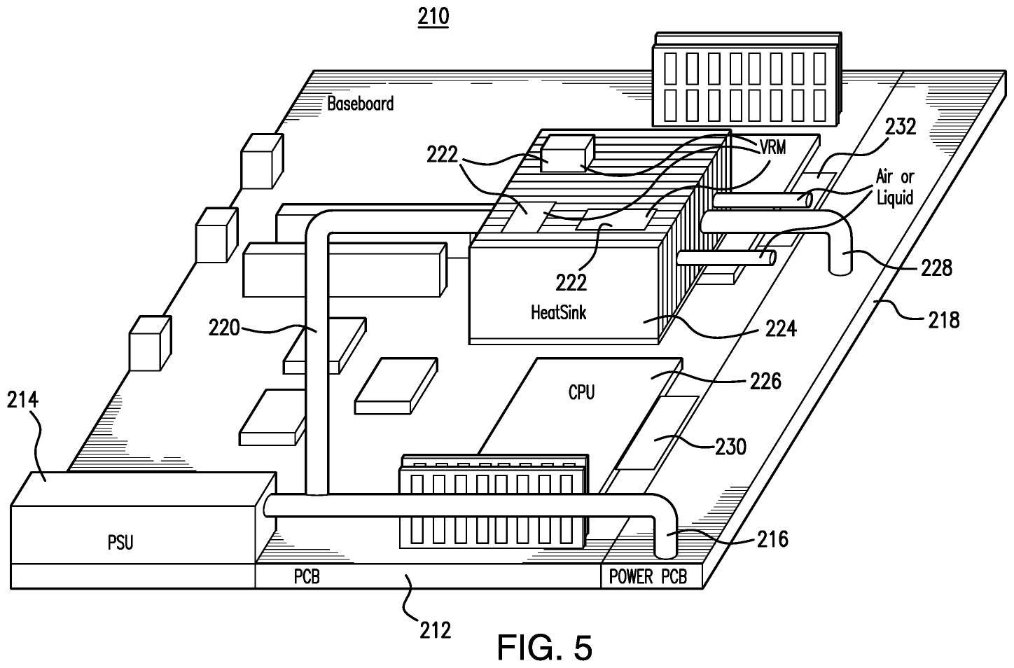

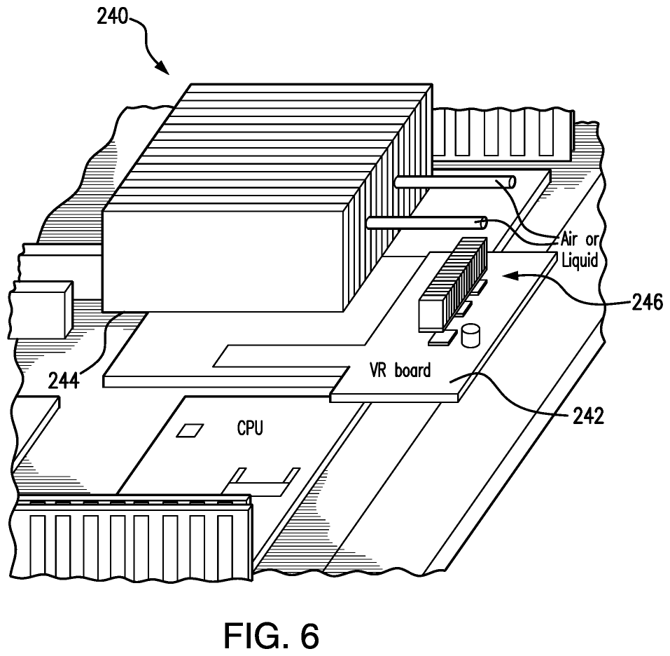

Turning now to FIG. 5, a computing system 210 is shown in which a main circuit board 212 includes a PSU 214 that uses a first power delivery path 220 (e.g., cable and/or busbar) to supply power directly to a plurality of VRMs 222 mounted to a heat sink 214 that functions as a thermal dissipation assembly for a CPU 226. Alternatively, the PSU 214 may use a second power delivery path 216 to supply power to a power board 218, which in turn uses a third power delivery path 228 to supply power to the VRMs 222 on the heat sink 214. In an embodiment, high speed channels 230 and 232 support IO communications in the computing system 210. Placing the VRMs 222 on the heat sink 214 shortens the power delivery path from the VRMs 22 to the CPU 226. Additionally, partitioning the VR into the separate VRMs 222 enables the VRMs to be easily designed with flexible PCB thicknesses and layers to meet design and cost requirements. Moreover, the illustrated solution enables voltage input pins (e.g., VCCIN pins) to be used for other purposes such as, for example, high speed IO (HSIO). In addition, form factor optimizations may involve substantial package size reductions. The illustrated solution also provides more routing space on the main circuit board 212 (e.g., HSIO fanout).

FIG. 6 shows a computing system 240 in which a regulator board 242 is electrically coupled to a heat sink 244 and a voltage regulator 246 is mounted to the regulator board 242. Thus, the illustrated example provides a pure high current power delivery path depending on requirements. In one embodiment, the heat sink 244 is used as a power delivery path and a ground connection. In another embodiment, the heat sink 244 is used as ground connection and a separate path is used for power delivery. Although loadline optimization in the computing system 240 may not be as effective as the computing system 210 (FIG. 5), there may be less impact on cooling performance. Additionally, a unified cooling solution can be used to cool both the CPU and the voltage regulator 246.

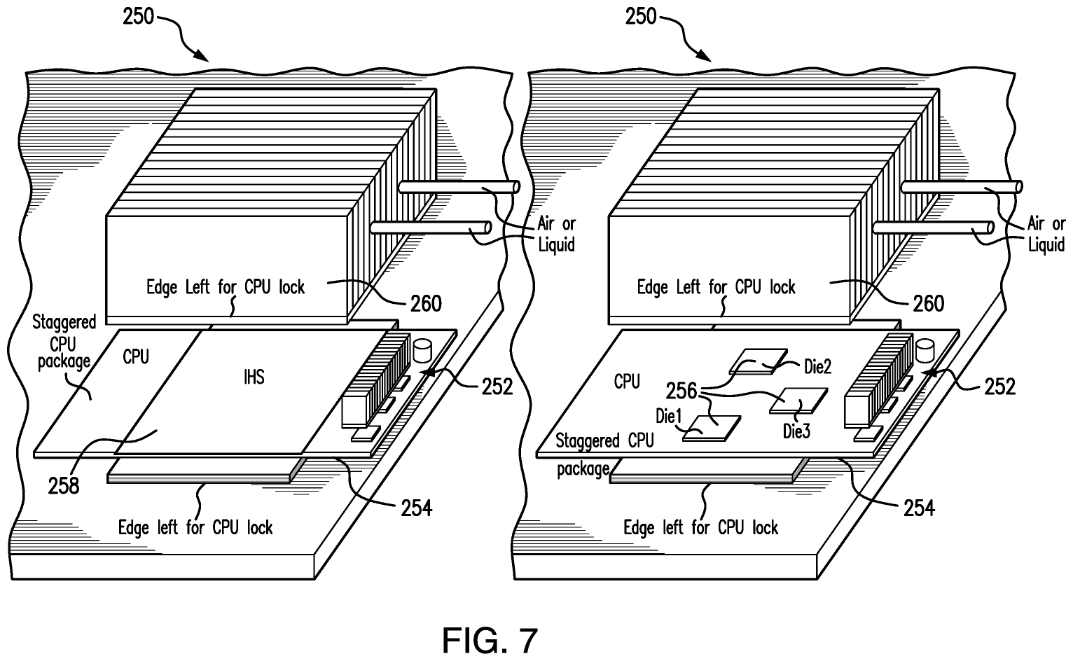

FIG. 7 shows a computing system 250 in which a voltage regulator 252 shares a package substrate 254 with a plurality of CPU dies 256. An integrated heat spreader (IHS) 258 may be positioned between the CPU dies 256 and a heat sink 260. The illustrated solution enables the bottom of the package to be kept small, with a staggered form factor. Additionally, a unified cooling solution can be used to cool both the CPU dies 256 and the voltage regulator 252.

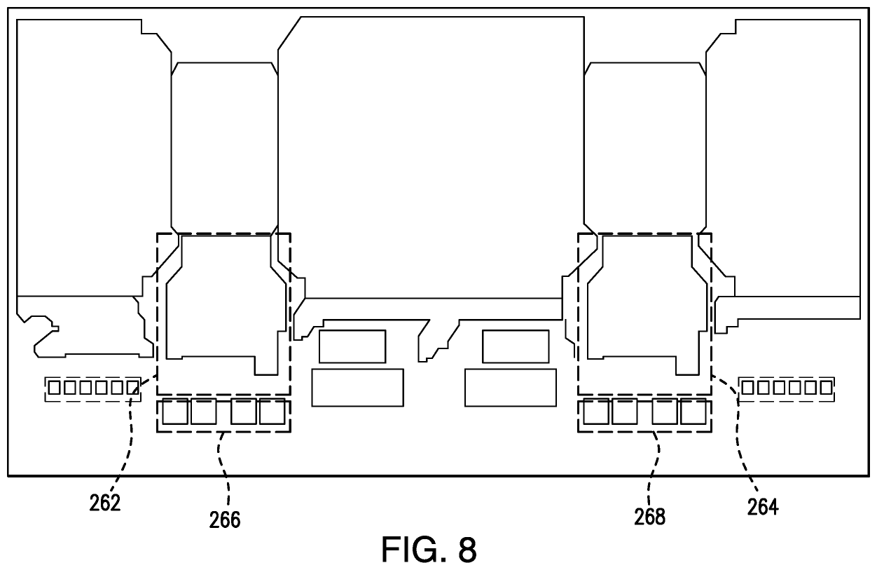

FIG. 8 demonstrates that first regions 262 and 264 may be used for CPU power delivery and second regions 266 and 268 may be used for high speed signal to storage channels.

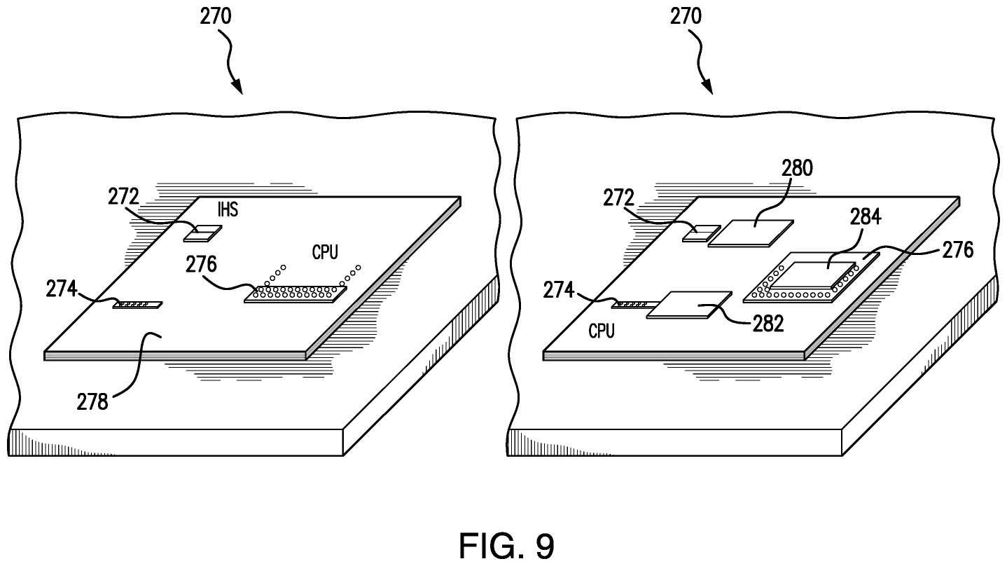

FIG. 9 shows a CPU package 270 in which connection points 272, 274 and 276 are provided through an IHS 278 to multiple VRM outputs. More particularly, a first connection point 272 is electrically coupled to a first VRM output and a power pin at a center of a first CPU die 280 and delivers power via an upper layer (but not the top layer) of the first CPU die 280. In such a case, high speed signals may be routed to lower layers of the first CPU die 280, and then to bottom layers of the first CPU die 280.

A second connection point 274 may be electrically coupled to a second VRM output and a power pin at a center of a second CPU die 282. In an embodiment, the second connection point 274 delivers power via an upper layer of the second CPU die 282, wherein high speed signals are routed to lower layers of the second CPU die 282, and then to bottom layers of the second CPU die 282.

Similarly, a third connection point 276 may be electrically coupled to a third VRM output and a power pin at a center of a third CPU die 284. In an embodiment, the third connection point 276 delivers power via an upper layer of the third CPU die 284, wherein high speed signals are routed to lower layers of the third CPU die 284, and then to bottom layers of third CPU die 284.

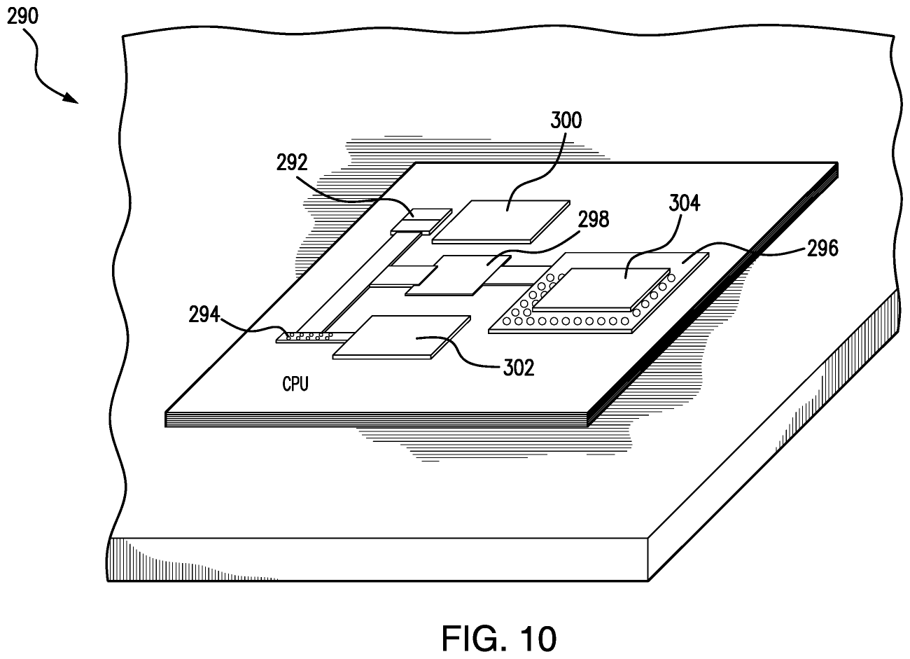

FIG. 10 shows a portion of a CPU package 290 (e.g., with an IHS removed). In the illustrated example, connection points 292, 294 and 296 are provided to a single VRM output 298. More particularly, a first connection point 292 is electrically coupled to the single VRM output 298 and a power pin at a center of a first CPU die 300 and delivers power via an upper layer (but not the top layer) of the first CPU die 300. In such a case, high speed signals may be routed to lower layers of the first CPU die 300, and then to bottom layers of the first CPU die 300.

A second connection point 294 may be electrically coupled to the single VRM output 298 and a power pin at a center of a second CPU die 302. In an embodiment, the second connection point 294 delivers power via an upper layer of the second CPU die 302, wherein high speed signals are routed to lower layers of the second CPU die 302, and then to bottom layers of the second CPU die 302.

Similarly, a third connection point 296 may be electrically coupled to the single VRM output 298 and a power pin at a center of a third CPU die 304. In an embodiment, the third connection point 296 delivers power via an upper layer of the third CPU die 304, wherein high speed signals are routed to lower layers of the third CPU die 304, and then to bottom layers of third CPU die 304.

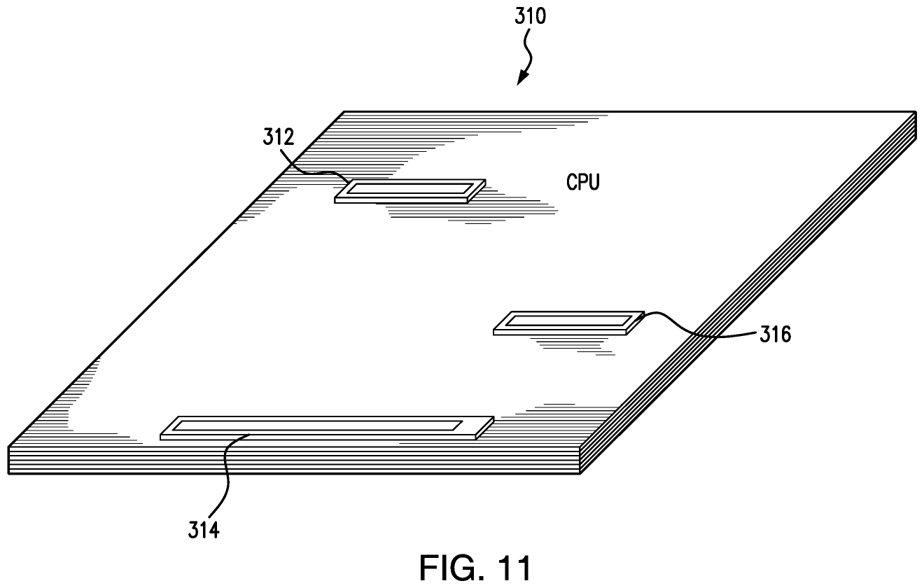

FIG. 11 shows a CPU package 310 having a first connector 312, a second connector 314, and a third connector 316 integrated onto the CPU package 310. In an embodiment, VRMs (not shown) are installed into the connectors 312, 314 and 316.

The processing units described herein may include may be implemented in one or more modules as a set of logic instructions stored in a machine- or computer-readable storage medium such as random access memory (RAM), read only memory (ROM), programmable ROM (PROM), firmware, flash memory, etc., in configurable hardware such as, for example, programmable logic arrays (PLAs), field programmable gate arrays (FPGAs), complex programmable logic devices (CPLDs), in fixed-functionality hardware using circuit technology such as, for example, application specific integrated circuit (ASIC), complementary metal oxide semiconductor (CMOS) or transistor-transistor logic (TTL) technology, or any combination thereof.

A semiconductor apparatus (e.g., chip and/or package) may include one or more substrates (e.g., silicon, sapphire, gallium arsenide) and logic (e.g., transistor array and other integrated circuit/IC components) coupled to the substrate(s). The logic may be implemented at least partly in configurable or fixed-functionality hardware. In one example, the logic includes transistor channel regions that are positioned (e.g., embedded) within the substrate(s). Thus, the interface between the logic and the substrate(s) may not be an abrupt junction. The logic may also be considered to include an epitaxial layer that is grown on an initial wafer of the substrate(s).

Additionally, the computing systems may generally be part of an electronic device/platform having computing functionality (e.g., personal digital assistant/PDA, notebook computer, tablet computer, convertible tablet, server), communications functionality (e.g., smart phone), imaging functionality (e.g., camera, camcorder), media playing functionality (e.g., smart television/TV), wearable functionality (e.g., watch, eyewear, headwear, footwear, jewelry), vehicular functionality (e.g., car, truck, motorcycle), robotic functionality (e.g., autonomous robot), Internet of Things (IOT) functionality, etc., or any combination thereof.

Technology described herein therefore provides performance and form factor benefits by avoiding package size increases due to the addition of power and ground pins. The technology also reduces package thickness (e.g., “system Z) by avoiding an increase in PCB layers. In addition, the technology improves power delivery through power loss reduction. For example, eliminating the power delivery (PD) path through conventional package BGAs (ball grid arrays) and a power plane that introduces more IR drop shortens the overall path and inductance loop. Accordingly, the loadline is improved for better performance. Additional advantages are also achieved through Cu plates integrated with vapor chambers to bring power from on board VRs. For example, flexibility is enhanced with respect to VR placement and location in the platform/computing system. Moreover, inductor on board placement is dictated by the power ballmap/package quadrant.

Moreover, the technology provides easier board layout and shorter IO channel reach. For example, with most of the VR components moved away from the board, the breakout and routing of the IO channel is easier and more straightforward (e.g., no wrapping around the VR components is needed). Indeed, shorter IO channel route lengths may potentially reduce board cost. The technology described herein also provides better thermal dissipation for power—Cu plates carrying power are attached to a vapor chamber to dissipate thermal directly from VR and the SOC (system on chip). Better performance can be achieved due to the thermal improvements.

### ADDITIONAL NOTES AND EXAMPLES

Example 1 includes a performance-enhanced computing system comprising a voltage regulator, a board assembly including a die and a circuit board electrically coupled to a first side of the die, and a thermal dissipation assembly thermally and electrically coupled to a second side of the die, wherein the thermal dissipation assembly is further electrically coupled to the voltage regulator.
Example 2 includes the computing system of Example 1, wherein the thermal dissipation assembly provides a power delivery path from the voltage regulator to the second side of the die.
Example 3 includes the computing system of Example 2, wherein the thermal dissipation assembly further provides a ground connection from the second side of the die to the voltage regulator.
Example 4 includes the computing system of Example 1, wherein the circuit board provides a ground connection from the first side of the die to the voltage regulator.
Example 5 includes the computing system of Example 1, wherein the voltage regulator is mounted to the thermal dissipation assembly.
Example 6 includes the computing system of Example 5, wherein the voltage regulator includes a plurality of voltage regulator modules.
Example 7 includes the computing system of Example 1, wherein the voltage regulator is mounted to the circuit board.
Example 8 includes the computing system of Example 1, further including a regulator board electrically coupled to the thermal dissipation assembly, wherein the voltage regulator is mounted to the regulator board.
Example 9 includes the computing system of Example 1, further including a plurality of signal contacts electrically coupled to the circuit board, and a package substrate electrically coupled to the plurality of signal contacts and the first side of the die.
Example 10 includes the computing system of Example 9, wherein the voltage regulator is mounted to the package substrate.
Example 11 includes the computing system of Example 1, wherein the second side of the includes a plurality of power contacts.
Example 12 includes the computing system of any one of Examples 1 to 11, wherein the thermal dissipation assembly includes a heat sink.
Example 13 includes the computing system of any one of Examples 1 to 11, wherein the thermal dissipation assembly includes a heat spreader.
Example 14 includes the computing system of Example 1, wherein the thermal dissipation assembly includes a vapor chamber.
Example 15 includes the computing system of Example 14, further including a plurality of copper plates electrically coupled to the voltage regulator and a package substrate containing the die, wherein the plurality of copper plates are further thermally coupled to the vapor chamber.
Example 16 includes the computing system of Example 15, wherein each copper plate provides a dedicated power delivery rail from the voltage regulator to the package substrate.
Example 17 includes the computing system of Example 15, wherein a first end of each copper plate includes a pogo pin electrically coupled to the package substrate.
Example 18 includes the computing system of Example 15, wherein a second end of each copper plate includes a spring clip that mates with a terminal of a charge storage device associated with the VR.
Example 19 includes the computing system of Example 15, further including a thermally conductive adhesive positioned between the thermal dissipation assembly and the plurality of copper plates.
Example 20 includes the computing system of Example 15, further including a copper pedestal positioned between the vapor chamber and the second side of the die.
Example 21 includes the computing system of Example 15, wherein the circuit board provides a ground connection from the first side of the die to the voltage regulator.
Example 22 includes a computing system comprising a board assembly including a die and a circuit board electrically coupled to a first side of the die, wherein the circuit board includes a voltage regulator, a thermal dissipation assembly, and a plurality of copper plates electrically coupled to the voltage regulator and a package substrate containing the die, wherein the plurality of copper plates are further thermally coupled to the thermal dissipation assembly.
Example 23 includes the computing system of Example 22, wherein each copper plate provides a dedicated power delivery rail from the voltage regulator to the package substrate.
Example 24 includes the computing system of Example 22, wherein a first end of each copper plate includes a pogo pin electrically coupled to the package substrate.
Example 25 includes the computing system of Example 22, wherein a second end of each copper plate includes a spring clip that mates with a terminal of a charge storage device associated with the VR.
Example 26 includes the computing system of Example 22, further including a thermally conductive adhesive positioned between the thermal dissipation assembly and the plurality of copper plates.
Example 27 includes the computing system of Example 22, further including a copper pedestal positioned between the thermal dissipation assembly and a second side of the die.
Example 28 includes the computing system of Example 22, wherein the circuit board provides a ground connection from the first side of the die to the voltage regulator.
Example 29 includes the computing system of any one of Examples 22 to 28, wherein the thermal dissipation assembly includes a vapor chamber.

Embodiments are applicable for use with all types of semiconductor integrated circuit (“IC”) chips. Examples of these IC chips include but are not limited to processors, controllers, chipset components, programmable logic arrays (PLAs), memory chips, network chips, systems on chip (SoCs), SSD/NAND controller ASICs, and the like. In addition, in some of the drawings, signal conductor lines are represented with lines. Some may be different, to indicate more constituent signal paths, have a number label, to indicate a number of constituent signal paths, and/or have arrows at one or more ends, to indicate primary information flow direction. This, however, should not be construed in a limiting manner. Rather, such added detail may be used in connection with one or more exemplary embodiments to facilitate easier understanding of a circuit. Any represented signal lines, whether or not having additional information, may actually comprise one or more signals that may travel in multiple directions and may be implemented with any suitable type of signal scheme, e.g., digital or analog lines implemented with differential pairs, optical fiber lines, and/or single-ended lines.

Example sizes/models/values/ranges may have been given, although embodiments are not limited to the same. As manufacturing techniques (e.g., photolithography) mature over time, it is expected that devices of smaller size could be manufactured. In addition, well known power/ground connections to IC chips and other components may or may not be shown within the figures, for simplicity of illustration and discussion, and so as not to obscure certain aspects of the embodiments. Further, arrangements may be shown in block diagram form in order to avoid obscuring embodiments, and also in view of the fact that specifics with respect to implementation of such block diagram arrangements are highly dependent upon the computing system within which the embodiment is to be implemented, i.e., such specifics should be well within purview of one skilled in the art. Where specific details (e.g., circuits) are set forth in order to describe example embodiments, it should be apparent to one skilled in the art that embodiments can be practiced without, or with variation of, these specific details. The description is thus to be regarded as illustrative instead of limiting.

The term “coupled” may be used herein to refer to any type of relationship, direct or indirect, between the components in question, and may apply to electrical, mechanical, fluid, optical, electromagnetic, electromechanical or other connections. In addition, the terms “first”, “second”, etc. may be used herein only to facilitate discussion, and carry no particular temporal or chronological significance unless otherwise indicated.

As used in this application and in the claims, a list of items joined by the term “one or more of” may mean any combination of the listed terms. For example, the phrases “one or more of A, B or C” may mean A; B; C; A and B; A and C; B and C; or A, B and C.

Those skilled in the art will appreciate from the foregoing description that the broad techniques of the embodiments can be implemented in a variety of forms. Therefore, while the embodiments have been described in connection with particular examples thereof, the true scope of the embodiments should not be so limited since other modifications will become apparent to the skilled practitioner upon a study of the drawings, specification, and following claims.

We claim:

1. A computing system comprising:
a voltage regulator;
a board assembly including a die and a circuit board electrically coupled to a first side of the die; and
a thermal dissipation assembly thermally and electrically coupled to a second side of the die, wherein the thermal dissipation assembly is further electrically coupled to the voltage regulator.

2. The computing system of claim 1, wherein the thermal dissipation assembly provides a power delivery path from the voltage regulator to the second side of the die.

3. The computing system of claim 2, wherein the thermal dissipation assembly further provides a ground connection from the second side of the die to the voltage regulator.

4. The computing system of claim 1, wherein the circuit board provides a ground connection from the first side of the die to the voltage regulator.

5. The computing system of claim 1, wherein the voltage regulator is mounted to the thermal dissipation assembly or the circuit board.

6. The computing system of claim 1, further comprising a regulator board electrically coupled to the thermal dissipation assembly, wherein the voltage regulator is mounted to the regulator board.

7. The computing system of claim 1, further comprising:
a plurality of signal contacts electrically coupled to the circuit board; and
a package substrate electrically coupled to the plurality of signal contacts and the first side of the die;
wherein the voltage regulator is mounted to the package substrate.

8. The computing system of claim 1, wherein the second side of the die includes a plurality of power contacts.

9. The computing system of claim 1, wherein the thermal dissipation assembly includes a heat sink, a heat spreader, or a vapor chamber.

10. The computing system of claim 9, wherein the thermal dissipation assembly includes the vapor chamber, and wherein the computer system further comprises a plurality of copper plates electrically coupled to the voltage regulator and a package substrate containing the die, wherein the plurality of copper plates are further thermally coupled to the vapor chamber.

11. The computing system of claim 10, wherein individual copper plates of the plurality of copper plates provide a dedicated power delivery rail from the voltage regulator to the package substrate.

12. The computing system of claim 10, wherein a first end of the respective copper plates includes a pogo pin electrically coupled to the package substrate, and wherein a second end of the respective copper plates includes a spring clip that mates with a terminal of a charge storage device associated with the voltage regulator.

13. The computing system of claim 10, further comprising:
a thermally conductive adhesive positioned between the thermal dissipation assembly and the plurality of copper plates; or
a copper pedestal positioned between the vapor chamber and the second side of the die.

14. An apparatus comprising:
a board assembly including a die and a circuit board electrically coupled to a first side of the die, wherein the circuit board includes a voltage regulator;
a thermal dissipation assembly; and
a plurality of copper plates electrically coupled to the voltage regulator and a package substrate containing the die, wherein the plurality of copper plates are further thermally coupled to the thermal dissipation assembly.

15. The apparatus of claim 14, wherein individual copper plates of the plurality of copper plates provide a dedicated power delivery rail from the voltage regulator to the package substrate.

16. The apparatus of claim 14, wherein the respective copper plates include a pogo pin electrically coupled to the package substrate.

17. The apparatus of claim 14, wherein the respective copper plates include a spring clip that mates with a terminal of a charge storage device associated with the voltage regulator.

18. The apparatus of claim 14, further comprising a thermally conductive adhesive positioned between the thermal dissipation assembly and the plurality of copper plates.

19. The apparatus of claim 14, further comprising a copper pedestal positioned between the thermal dissipation assembly and a second side of the die.

20. The apparatus of claim 14, wherein the thermal dissipation assembly includes a vapor chamber.
